(19) United States
(12) Patent Application Publication
(10) Pub. No.: US 2026/0113914 A1
(43) Pub. Date: Apr. 23, 2026

(54) COOLER FOR POWER MODULES

(71) Applicant: HYUNDAI MOBIS CO., LTD., Seoul (KR)

(72) Inventors: Keun Jae LEE, Yongin-si (KR); Seung Jun NOH, Yongin-si (KR)

(73) Assignee: HYUNDAI MOBIS CO., LTD., Seoul (KR)

(21) Appl. No.: 19/304,931

(22) Filed: Aug. 20, 2025

(30) Foreign Application Priority Data
Oct. 23, 2024 (KR) 10-2024-0145927

(51) Int. Cl. H05K 7/20

(52) U.S. Cl. CPC H05K 7/20927; H05K 7/209

(57) ABSTRACT

A cooler for power modules includes a cooling body defining upper and lower channels separated by a separation plate, the upper and lower channels each having opened upper and lower surfaces, a channel wall disposed at the upper and lower channels, the channel wall being disposed in a direction crossing a flow direction of a cooling medium to allow the cooling medium to move while overflowing the channel wall, and a heat sink coupled to each of the upper surface of the upper channel and the lower surface of the lower channel and having an outer surface to face outwardly of the cooling body and to allow a power module to be thermally connected thereto and an inner surface to face inwardly of the cooling body and including a cooling wall to exchange heat with the cooling medium.

### CROSS REFERENCE TO RELATED APPLICATION

This application claims priority from Korean Patent Application No. 10-2024-0145927 filed on October 23, 2024 in the Korean Intellectual Property Office, the disclosure of which is incorporated herein by reference in its entirety.

### BACKGROUND

### Field of the disclosure

The present disclosure relates to a cooler for power modules which may be installed in a power conversion device or the like such as an inverter or a converter.

### Description of the Related Art

Batteries discharge direct current (DC), but devices such as electric motors used to drive electric vehicles, etc. require alternating current (AC) electricity. Therefore, an object configured to operate using energy supplied from an energy storage device such as a battery or the like requires an inverter configured to convert DC power into AC power.

The inverter converts DC power into AC power. Through adjustment of the frequency and voltage of the AC power, the inverter may control the rotational speed and output of an electric motor. In this way, acceleration and deceleration of an electric vehicle may be regulated.

Meanwhile, when the inverter operates to convert DC power into AC power, thermal energy is generated. The generated thermal energy raises the temperature of the inverter. As the temperature of the inverter increases, it becomes difficult for the inverter to operate normally. Therefore, the inverter requires a cooler configured to cool components of the inverter.

Meanwhile, improving the cooling efficiency of the inverter may lead to increased electric range of electric vehicles. As a result, various methods to enhance the cooling efficiency of the inverter are currently being researched.

The above matters disclosed in this section are merely for enhancement of understanding of the general background of the disclosure and should not be taken as an acknowledgement or any form of suggestion that the matters form the related art already known to a person skilled in the art.

### SUMMARY

Therefore, the present disclosure has been made in view of the above problems, and it is an aspect of the present disclosure to provide a cooler for power modules which is configured to enhance the cooling efficiency of an inverter.

Aspects of the present disclosure are not limited to the above-described aspect, and other aspects of the present disclosure not yet described will be more clearly understood by those skilled in the art from the following detailed description.

In accordance with an aspect of the present disclosure, the above and other aspects may be accomplished by the provision of a cooler for power modules including a cooling body defining an upper channel and a lower channel separated from each other by a separation plate, the upper channel and the lower channel each having an opened upper surface and an opened lower surface; a channel wall disposed at the upper channel and the lower channel of the cooling body, the channel wall being disposed in a direction crossing a flow direction of a cooling medium to allow the cooling medium to move while overflowing the channel wall; and a heat sink coupled to each of the upper surface of the upper channel and the lower surface of the lower channel, the heat sink having an outer surface configured to face outwardly of the cooling body and to allow a power module to be thermally connected to the outer surface and an inner surface configured to face inwardly of the cooling body and including a cooling wall configured to exchange heat with the cooling medium.

In an embodiment, the channel wall may include a plurality of channel walls spaced apart from one another in the flow direction of the cooling medium in the upper channel or the lower channel.

In an embodiment, the channel wall may interconnect facing inner surfaces of the upper channel or the lower channel in the direction crossing the flow direction of the cooling medium.

In an embodiment, the channel wall may be bent multiple times.

In an embodiment, the upper channel or the lower channel may be divided into an introduction space and an exit space by the channel wall. The channel wall may include a first extension extending from the introduction space toward the exit space, a bent portion reversely bent from the first extension, and a second extension extending reversely from the bent portion in a direction from the exit space toward the introduction space. The cooling medium in the introduction space introduced among the first extension, the bent portion, and the second extension may flow to the exit space while overflowing the channel wall.

In an embodiment, the channel wall may extend in a length direction of the cooling body, and the cooling wall may extend in a width direction of the cooling body. The cooling wall may be disposed in plural such that a plurality of cooling walls is spaced apart from one another in the length direction of the cooling body, and is spaced apart from the cooling body to define a space functioning as a cooling medium movement passage.

In an embodiment, a cooling medium inlet and a cooling medium outlet may be disposed at front and rear surfaces of the cooling body, respectively.

In an embodiment, each of the upper channel and the lower channel of the cooling body may be divided into a plurality of heat exchange spaces in the flow direction of the cooling medium, and each of the upper channel and the lower channel may be reduced in cross-sectional area between adjacent heat exchange spaces.

In an embodiment, at a point where the channel cross-sectional area of the cooling body is reduced, a fastening hole is disposed for coupling of the cooling body and the heat sink.

In an embodiment, the channel wall may be disposed at each of the heat exchange spaces.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an exploded view of a cooler for power modules according to an embodiment of the present disclosure;

FIG. 2 is a view showing a heat sink of the cooler for power modules according to the present disclosure;

FIG. 3 is an enlarged view of a portion A of FIG. 2; and

FIG. 4 is a schematic view showing movement of a cooling medium in the heat sink.

### DETAILED DESCRIPTION

In the following description of the embodiments of the present disclosure, a detailed description of known technologies incorporated herein will be omitted when it may obscure the subject matter of the embodiments of the present disclosure. In addition, the embodiments of the present disclosure will be more clearly understood from the accompanying drawings and should not be limited by the accompanying drawings, and it is to be appreciated that all changes, equivalents, and substitutes that do not depart from the spirit and technical scope of the present disclosure are encompassed in the present disclosure. The following description is not intended to limit the present disclosure to the precise forms or particular fields of use disclosed. As such, it is contemplated that various alternate embodiments and/or modifications to the present disclosure, whether explicitly described or implied herein, are possible in light of the disclosure. A person of ordinary skill in the art will recognize that changes may be made in form and detail without departing from the scope of the present disclosure.

The present disclosure will be described with reference to specific embodiments. However, as one skilled in the art will appreciate, various embodiments disclosed herein may be modified or otherwise implemented in various other ways without departing from the spirit and scope of the disclosure. Accordingly, the following description is to be considered as illustrative and is for the purpose of teaching those skilled in the art the manner of making and using various embodiments. It is to be understood that the forms of disclosure shown and described herein are to be taken as representative embodiments. Equivalent elements, materials, processes or steps may be substituted for those representatively illustrated and described herein. Expressions such as “including”, “comprising”, “incorporating”, “consisting of”, “have”, and “is” used to describe the present disclosure are intended to be construed in a non-exclusive manner, namely, in a manner allowing items, components or elements not explicitly described also to be present. Unless clearly used otherwise, singular expressions should be interpreted as including a plural meaning.

Furthermore, various embodiments disclosed herein are to be taken in the illustrative and explanatory sense, and should in no way be construed as limitative of the present disclosure. All references as to joining (e.g., attached, affixed, coupled, connected, and the like) are only used to aid understanding of the present disclosure, and may not create limitations, particularly as to the position, orientation, or use of the configuration or the method disclosed herein. Therefore, references as to joining, if any, are to be construed broadly. Moreover, such references as to joining do not necessarily infer that two elements are directly connected to each other. Additionally, all numerical terms, such as, but not limited to, “first”, “second”, “third”, “primary”, “secondary”, “main” or any other ordinal or numerical terms, should also be taken only as identifiers to assist understanding of various elements, embodiments, variations or modifications of the present disclosure, and may not mean any limitation as to embodiment, variation or modification of any element or any limitation as to the order or preference thereof. That is, although such expressions may be used to describe various constituent elements, these constituent elements are not limited by the expressions associated therewith. Such expression is used only for distinguishment of one constituent element from another constituent element.

The suffixes “module” and “unit” of elements herein are used for convenience of description and thus may be used interchangeably and do not have any distinguishable meanings or functions.

In the case where an element is "connected" or "linked" to another element, it should be understood that the element may be directly connected or linked to the other element, or another element may be present therebetween. Conversely, in the case where an element is "directly connected" or "directly linked" to another element, it should be understood that no other element is present therebetween.

A controller may include a communication device configured to communicate with another controller or a sensor, for control of a function to be performed thereby, a memory configured to store an operating system, logic commands, input/output information, etc., and at least one processor, etc. configured to execute discrimination, calculation, determination, etc. required for control of the function to be performed.

In addition, the term “unit” or “control unit” used in specific terminology is only a term widely used for designation of a controller for controlling a particular function of a vehicle and, as such, does not mean a generic functional unit.

The controller may include a communication device configured to communicate with another controller or a sensor for control of a function to be performed thereby, a memory configured to store an operating system, logic commands, input/output information, etc., and at least one processor configured to execute discrimination, calculation, determination, etc. required for control of the function to be performed.

Any number of components or a variety of components of any one of the configurations disclosed in the present disclosure may be included in the present disclosure. Such components may include any combination of characterized parts disclosed in the present disclosure, and may be arranged to constitute any one of various configurations disclosed in the present disclosure. Not only structures and arrangements of the components of the present disclosure, but also concepts as to use and operation thereof, may be applied not only to particular embodiments discussed in the present disclosure, but also to embodiments of any numbers and in any combinations. In the following description, embodiments including various characterized parts having various arrangements will be described with reference to the accompanying drawings.

Hereinafter, various embodiments disclosed in the present disclosure will be described in detail with reference to the accompanying drawings, and the same or similar elements are designated by the same reference numerals regardless of the numerals in the drawings and redundant description thereof will be omitted.

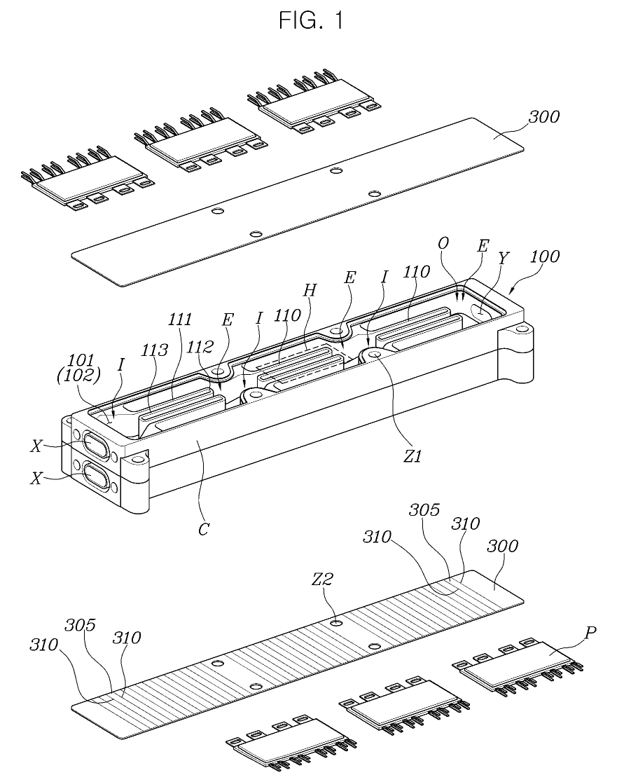

FIG. 1 is an exploded view of a cooler for power modules according to an embodiment of the present disclosure. Referring to FIG. 1, a cooling body 100 may be manufactured using aluminum or other metal materials. An upper channel 101 and a lower channel 102 are formed inside the cooling body 100. The upper channel 101 and the lower channel 102 have symmetrical structures, and the structure of the lower channel 102 can be understood through the structure of the upper channel 101. A separation plate is provided between the upper channel 101 and the lower channel 102. A cooling medium flows inside the cooling body 100 to cool a power module P. The separation plate may function to not only divide a channel, through which the cooling medium flows, into the upper channel 101 and the lower channel 102, but also to prevent mixing of the cooling medium flowing through the upper channel 101 and the cooling method flowing through the lower channel 102. Upper and lower surfaces of the cooling body 100 are formed with open surfaces O, respectively. A heat sink 300 may be coupled to each open surface O. The heat sink 300 is configured to thermally connect the cooling medium and the power module P in order to allow heat exchange therebetween.

The power module P includes a switching element which is a heat generating element. The switching element controls on/off of power required for driving of a motor. The switching element may be at least one of a bipolar junction transistor (BJT), a silicon controlled rectifier (SCR), a TRIAC, a unijunction transistor (UJT), a programmable unijunction transistor (PUT), a junction field effect transistor (JFET), a gate turn-off thyristor (GTO), a MOS controlled thyristor (MCT), an injection-enhanced gate transistor (IEGT), an insulated gate bipolar transistor (IGBT), a gate commutated thyristor (IGCT), a MOSFET, an intelligent power device (IPD) (semiconductor switch), or a diode element.

Inside the cooling body 100, a structure called a channel wall 110 is formed. The channel wall 110 is formed in a direction crossing a flow direction of the cooling medium. That is, assuming that the cooling medium flows in a forward/rearward direction of the cooling body 100, the channel wall 110 is formed in a left/right direction of the cooling body 100. The channel wall 110 is formed to have a lower height than side walls C constituting an outer shape of the cooling body 100. Cooling walls 310 of the heat sink 300, which will be described later, may contact an upper end of the channel wall 110. Alternatively, the cooling walls 310 of the heat sink 300 may be spaced apart from the upper end of the channel wall 110 by a predetermined distance. Additionally, a micro-channel 305, through which the cooling medium is movable, is formed between adjacent ones of the cooling walls 310 of the heat sink 300.

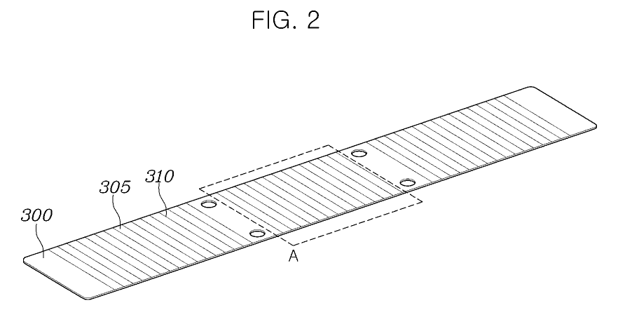

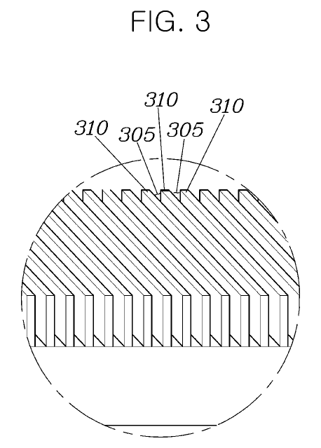

Specifically, referring to FIGS. 2 to 4, the cooling walls 310 are formed at the heat sink 300 to protrude as compared to remaining portions of the heat sink 300. The cooling walls 310 are formed in plural. Among the cooling walls 310, a micro-channel 305 is formed to allow flow of the cooling medium therethrough.

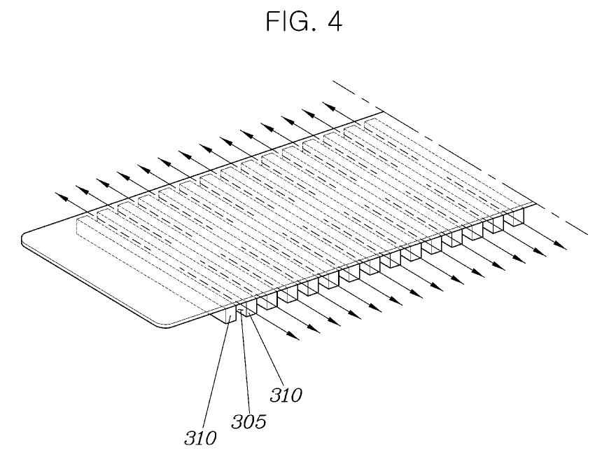

More specifically, the cooling medium entering the upper channel 101 or the lower channel 102 of the cooling body 100 is temporarily prevented from moving for a predetermined time by the channel wall 110. The cooling medium accumulates until the predetermined time elapses, and then enters the micro-channel 305 formed by the cooling walls 310, as shown in FIG. 4. The cooling medium then moves while overflowing the channel wall 110. This structure maximizes the contact time and cross-sectional area between the cooling medium and the heat sink 300. Accordingly, sufficient heat exchange of the cooling medium with the power module P may be achieved.

The heat sink 300 is coupled to each of the upper surface of the upper channel 101 and the lower surface of the lower channel 102, that is, each open surface O of the cooling body 100. The power module P is thermally connected to an outer surface of the heat sink 300 facing outwardly of the cooling body 100. Additionally, the cooling walls 310 described above are formed at an inner surface of the heat sink 300 facing inwardly of the cooling body 100. The cooling walls 310 not only serve as an a medium enabling heat exchange between the cooling medium and the power module P, but also form the micro-channel 305 allowing the cooling medium to overflow the channel wall 110 of the cooling body 100 in association with the channel wall 110.

The cooling walls 310 and the channel wall 110 may contact each other or may be spaced apart from each other by a predetermined distance. Additionally, some of the cooling walls 310 may be formed to contact the channel wall 110 or to be spaced apart from the channel wall 110 by a predetermined distance.

The cooling medium is initially prevented from moving by the channel wall 110. However, once the cooling medium accumulates in a predetermined amount or more, the cooling medium may pass over the channel wall 110 through the micro-channel 305 and, as such, subsequent movement of the cooling medium may be carried out. As the cooling medium strikes the channel wall 110 formed inside the cooling body 100, movement of the cooling medium exhibits a three-dimensional flow. Accordingly, the residence time of the cooling medium within the cooling body 100 may increase.

Similarly to the upper channel 101, the lower channel 102 may exhibit the same cooling medium movement behavior as the upper channel 101. That is, although the lower channel 102 is affected by gravity, movement of the cooling medium flowing through the lower channel 102 is prevented by the channel wall 110. As a result, only when the cooling medium accumulates in a predetermined amount or more, the cooling medium may pass over the channel wall 110 through the micro-channel 305 and, as such, subsequent movement of the cooling medium may be carried out.

Such flow of the cooling medium is referred to as “jet impinging”. Jet impinging is a method of directly spraying the cooling medium onto a local point to remove heat. To achieve heat exchange through jet impinging, a turbulent flow of the cooling medium should be utilized. That is, the cooling medium should flow in all directions of the cooling body 100, that is, in the length, height, and width directions of the cooling body 100, without flowing simply along the channel of the cooling body 100. When cooling is performed through the jet impinging method, it may be possible to optimize the cooling area in a required local region and to achieve proper mixing of the cooling medium. Accordingly, an enhancement in cooling efficiency may be achieved.

Meanwhile, in accordance with an embodiment, the channel wall 110 may be formed in plural such that a plurality of channel walls 110 is spaced apart from one another in a flow direction of the cooling medium in the upper channel 101 or the lower channel 102. As the plurality of channel walls 110 is formed in the flow direction of the cooling medium, the cooling medium may stay at multiple points within the cooling body 100. When the cooling medium accumulates in a sufficient amount to overflow the channel wall 110, movement of the cooling medium is continued. After overflowing one channel wall 110, the cooling medium is immediately prevented from moving by another channel wall 110. Similarly, once the cooling medium again accumulates in a sufficient amount to overflow the other channel wall 110, the cooling medium overflows the other channel wall 110 and as such, movement of the cooling medium is continued. In accordance with this method, it may be possible to increase the residence time of the cooling medium within the cooling body 100 and to increase the number of times when the cooling medium comes into contact with the cooling wall 310 while moving with irregular motion through collision with the channel walls 110.

Additionally, in an embodiment, the channel wall 110 may interconnect opposing inner surfaces of the upper channel 101 or lower channel 102 in a direction crossing the flow direction of the cooling medium. That is, the channel wall 110 interconnects the side walls C constituting the outer shape of the cooling body 100. The channel wall 110 has a structure configured to interconnect left and right walls C of the cooling body 100 in the width direction of the cooling body 100. The channel wall 110 is disposed in plural in the length direction of the cooling body 100. The channel wall 110 may be bent multiple times to interconnect the left and right walls C of the cooling body 100.

In an embodiment, the upper channel 101 or the lower channel 102 is divided into an introduction space I and an exit space E by the channel wall 110. The channel wall 110 is constituted by a first extension 111 extending from the introduction space I toward the exit space E, a bent portion 112 reversely bent from the first extension 111, and a second extension 113 extending reversely from the bent portion 112 in a direction from the exit space E toward the introduction space I. In this case, flow of the cooling medium is carried out in such a manner that the cooling medium in the introduction space I introduced among the first extension 111, the bent portion 112, and the second extension 113 flows to the exit space E while overflowing the channel wall 110.

Additionally, in an embodiment, the channel wall 110 may extend in the length direction of the cooling body 100, and the cooling wall 310 may extend in the width direction of the cooling body 100. The cooling wall 310 may be disposed in plural such that a plurality of cooling walls 310 is spaced apart from one another in the length direction of the cooling body 100. As shown in the drawings, the cooling wall 310 crosses the flow direction of the cooling medium. The cooling wall 310 may be formed to have a continuous shape and may be formed to have a rectangular shape. One surface of the rectangular cooling wall 310 may contact or face one surface of the channel wall 110 in a spaced state to form a micro-gap in order to allow the cooling medium to penetrate the micro-gap for movement thereof.

When the cooling medium moves to the next channel wall 110 through the micro-gap, movement of the cooling medium may be carried out in both the length direction and the width direction of the cooling body 100. Of course, increasing the amount of the cooling medium moving in the width direction of the cooling body 100 may increase the residence time of the cooling medium within the cooling body 100.

Meanwhile, a cooling medium inlet X configured to allow introduction of the cooling medium and a cooling medium outlet Y configured to allow discharge of the cooling medium may be formed at front and rear surfaces of the cooling body 100, respectively. When the cooling medium exits the cooling body 100 after cooling the power module P, the cooling medium may then be cooled again and re-enter the cooling body 100 through the cooling medium inlet X in order to again cool the power module P. In this case, a pump configured to pressurize the cooling medium may be provided in order to introduce the cooling medium into the cooling body 100.

The cooling medium may directly undergo compression, condensation, expansion, and evaporation, or may be indirectly cooled through heat exchange with another cooling medium.

The cooling medium inlet X and the cooling medium outlet Y may be configured as pairs connected to the upper channel 101 and the lower channel 102, respectively, without being limited thereto. A single cooling medium inlet X and a single cooling medium outlet Y may be formed to distribute the cooling medium to the upper channel 101 and the lower channel 102. Of course, it is preferable to form the cooling medium inlet X and the cooling medium outlet Y as pairs, in order to control the flow rate of the cooling medium to be constant.

Meanwhile, the cooling body 100, specifically, the upper channel 101 and the lower channel 102, may be divided into a plurality of heat exchange spaces H in the flow direction of the cooling medium. The heat exchange spaces H may be partitioned by the channel walls 110. That is, each heat exchange space H refers to a space where the cooling medium stays for a predetermined time and comes into contact with the cooling walls 310, that is, exchanges heat with the power module P.

Referring to FIG. 1, the number of the heat exchange spaces H may be determined in accordance with the number of power modules P disposed at the cooling body 100. In other words, each power module P corresponds to one heat exchange space H. Additionally, the channel, through which the cooling medium flows, may be reduced in cross-sectional area between adjacent ones of the heat exchange spaces H. As the cross-sectional area of the channel is reduced, the cooling medium moves to the next heat exchange space H in an accelerated state and, as such, may efficiently exchange heat with the next power module P. Additionally, at a point where the cross-sectional area of the channel of the cooling body 100 is reduced, a fastening hole Z1 is formed for coupling of the cooling body 100 and the heat sink 300. The heat sink 300 is bolted to the fastening hole Z1 and, as such, is fastened to the cooling body 100. It is also preferable to provide a sealing member (a gasket) along an interface where the heat sink 300 and the cooling body 100 are coupled to each other, in order to seal the heat sink 300 and the cooling body 100. The fastening hole Z1 of the cooling body 100 may be configured to accommodate a screw head or a threaded end of a screw. The heat sink 300 may also be provided with a hole Z2 corresponding to the fastening hole Z1 to receive a body of the screw.

In accordance with the cooler for power modules in the present disclosure, two independent channels are provided within the cooling body and, as such, heat sinks may be coupled to both surfaces of the cooling body, respectively. Accordingly, it may be possible to cool a large number of power modules.

The cooler for power modules is compact in size and has a reduced weight. Additionally, the number of processes required to manufacture the power modules may be reduced.

As a result, the cooler for power modules according to the present disclosure may enhance the power efficiency of electric vehicles equipped therewith.

Effects attainable in the present disclosure are not limited to the above-described effects, and other effects of the present disclosure not yet described will be more clearly understood by those skilled in the art from the above description.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A cooler for power modules comprising:
a cooling body defining an upper channel and a lower channel separated from each other by a separation plate, the upper channel and the lower channel each having an opened upper surface and an opened lower surface;
a channel wall disposed at the upper channel and the lower channel of the cooling body, the channel wall being disposed in a direction crossing a flow direction of a cooling medium to allow the cooling medium to move while overflowing the channel wall; and
a heat sink coupled to each of the upper surface of the upper channel and the lower surface of the lower channel, the heat sink having an outer surface configured to face outwardly of the cooling body and to allow a power module to be thermally connected to the outer surface and an inner surface configured to face inwardly of the cooling body and including a cooling wall configured to exchange heat with the cooling medium.

2. The cooler according to claim 1, wherein the channel wall includes a plurality of channel walls spaced apart from one another in the flow direction of the cooling medium in the upper channel or the lower channel.

3. The cooler according to claim 2, wherein the channel wall has a wall shape configured to interconnect facing inner surfaces of the upper channel or the lower channel in the direction crossing the flow direction of the cooling medium.

4. The cooler according to claim 1, wherein the channel wall is bent multiple times.

5. The cooler according to claim 4, wherein:
the upper channel or the lower channel is divided into an introduction space and an exit space by the channel wall;
the channel wall comprises a first extension extending from the introduction space toward the exit space, a bent portion reversely bent from the first extension, and a second extension extending reversely from the bent portion in a direction from the exit space toward the introduction space; and
the cooling medium in the introduction space introduced among the first extension, the bent portion, and the second extension flows to the exit space while overflowing the channel wall.

6. The cooler according to claim 1, wherein:
the channel wall extends in a length direction of the cooling body;
the cooling wall extends in a width direction of the cooling body; and
the cooling wall is disposed in plural such that a plurality of cooling walls is spaced apart from one another in the length direction of the cooling body, and is spaced apart from the cooling body to define a space functioning as a cooling medium movement passage.

7. The cooler according to claim 1, wherein a cooling medium inlet and a cooling medium outlet are disposed at front and rear surfaces of the cooling body, respectively.

8. The cooler according to claim 1, wherein:
each of the upper channel and the lower channel of the cooling body is divided into a plurality of heat exchange spaces in the flow direction of the cooling medium; and
each of the upper channel and the lower channel is reduced in cross-sectional area between adjacent heat exchange spaces.

9. The cooler according to claim 8, wherein, at a point where the channel cross-sectional area of the cooling body is reduced, a fastening hole is disposed for coupling of the cooling body and the heat sink.

10. The cooler according to claim 8, wherein the channel wall is disposed at each of the heat exchange spaces.
